(19) United States
(12) Patent Application Publication
(10) Pub. No.: US 2017/0178876 A1
(43) Pub. Date: Jun. 22, 2017

(54) Cu-Ga ALLOY SPUTTERING TARGET AND METHOD FOR MANUFACTURING SAME

(71) Applicant: MITSUBISHI MATERIALS CORPORATION, Tokyo (JP)

(72) Inventors: Keita Umemoto, Sanda-shi (JP); Shoubin Zhang, Sanda-shi (JP)

(21) Appl. No.: 15/302,010

(22) PCT Filed: Jul. 7, 2015
(86) PCT No.: PCT/JP2015/069510

§ 371 Date: Oct. 5, 2016

(30) Foreign Application Priority Data
Jul. 8, 2014 (JP) 2014-140261
Jun. 19, 2015 (JP) 2015-123998

(51) Int. Cl. H01J 37/34; C23C 14/34; C22F 1/08; C22C 9/00; B22F 1/00

(52) U.S. Cl. CPC H01J 37/3426; C22C 9/00; B22F 1/0085; C22F 1/08; C23C 14/3414

(57) ABSTRACT

A Cu—Ga alloy sputtering target includes, as a component composition, Ga: 0.1 to 40.0 at % and a balance including Cu and inevitable impurities, in which a porosity is 3.0% or lower, an average diameter of circumscribed circles of pores is 150 μm or less, and an average crystal grain size of Cu—Ga alloy particles is 50 μm or less.

### TECHNICAL FIELD

The present invention relates to a Cu—Ga alloy sputtering target for use in forming a Cu—In—Ga—Se compound film (hereinafter, also abbreviated as “CIGS film”), which is used as a light-absorbing layer of a thin-film solar cell, and a method of manufacturing the same.

Priority is claimed on Japanese Patent Application No. 2014-140261, filed Jul. 8, 2014, and Japanese Patent Application No. 2015-123998, filed Jun. 19, 2015, the contents of which are incorporated herein by reference.

### BACKGROUND ART

A Cu—In—Ga—Se quaternary alloy film has been developed in various ways. A Cu—Ga alloy sputtering target is a material which is necessary to manufacture a solar cell in which a Cu—In—Ga—Se quaternary alloy film (CIGS film) formed using a selenization (Se) process is used as a light-absorbing layer. In the selenization process, for example, a laminated film is formed by sputtering CuGa to form a CuGa layer having a thickness of about 500 nm and then sputtering In to form an In layer having a thickness of about 500 nm, and this laminated film is heated in H₂Se gas at 500° C. such that Se is diffused into CuGaIn to form a CuInGaSe compound film.

Recently, a technique of increasing the area of a substrate used in a solar cell to reduce the costs has been actively studied. Accordingly, an increase in the area of a Cu—Ga alloy sputtering target has also been required. A characteristic required to increase the area of a sputtering target is resistance to high-power sputtering. In particular, in a case where a cylindrical sputtering target is used, the cooling efficiency is higher than that in a case where a flat sputtering target is used. Therefore, a cylindrical sputtering target requires higher resistance to a high power density than a flat sputtering target.

Numerous discussions have been held on the porosity in a Cu—Ga alloy sputtering target (for example, refer to PTLs 1 to 3). According to these discussions, in a case where a sputtering target is manufactured using a Cu—Ga alloy sintered body, the most important requirement is a high relative density of the sintered body. The relative density is expressed by a ratio obtained by dividing the actual absolute density by the theoretical density of a target having the composition. A low relative density represents that a large number of pores are present in a sputtering target. In this case, when internal pores are exposed during sputtering, splashing or abnormal discharge starting from near the pores is likely to be generated. Therefore, it is believed that it is preferable that pores be present in a sputtering target such that the porosity in the sputtering target is, for example, 1.0% or lower.

### CITATION LIST

### Patent Literature

[PTL 1] Japanese Unexamined Patent Application, First Publication No. 2010-265544

[PTL 2] Japanese Unexamined Patent Application, First Publication No. 2012-201948

[PTL 3] Japanese Unexamined Patent Application, First Publication No. 2013-142175

### DISCLOSURE OF INVENTION

### Technical Problem

As described above, in the related art, discussions have been held on only the porosity in a Cu—Ga alloy sputtering target, and the shape and size of pores in a Cu—Ga alloy sputtering target have not been discussed. As long as a Cu—Ga alloy sputtering target is manufactured using a sintered body, the formation of pores in the target is unavoidable. However, in the sintered body, micropores and macropores may be present together. In a case where only micropores are present in a sputtering target, the generation of abnormal discharge can be reduced even during high-power sputtering by simply limiting the porosity to be, for example, 1.0% or lower. However, in a case where macropores are present in a sputtering target, splashing or abnormal discharge starting from near the pores is likely to be generated even after limiting the porosity to be, for example, 1.0% or lower. Therefore, with a sputtering target in which only the porosity is controlled to be 1.0% or lower, high-power sputtering cannot be stably performed. This phenomenon is significant in a case where a sputtering target having a large area is used.

An object of the present invention is to provide a Cu—Ga alloy sputtering target in which the shape and size of pores are defined. With this configuration, even during high-power sputtering, the generation of splashing or abnormal discharge can be suppressed, and sputtering can be stably performed.

### Solution to Problem

In the related art, discussions have been held on only the porosity in a Cu—Ga alloy sputtering target, and the shape and size of pores in a Cu—Ga alloy sputtering target have not been discussed. Therefore, various Cu—Ga alloy sputtering targets were prepared, and sputtering characteristics thereof were evaluated. As a result, it was verified that, with the configuration regarding the porosity of a Cu—Ga alloy sputtering target prepared in the related art, abnormal discharge was not generated during low-power sputtering but was generated during high-power sputtering. It is presumed to be that abnormal discharge is generated due to the presence of micropores and macropores, in particular, the presence of macropores in a target. In order to suppress the generation of abnormal discharge, it is important to control the shape and size of pores in a target. In the present invention, the shape and size of pores in a sputtering target are controlled. With this sputtering target, abnormal discharge is not generated even during high-power sputtering.

A representative example of the Cu—Ga alloy sputtering target according to the present invention was manufactured using a method including: reducing and deoxidizing Cu—Ga alloy powder including 35 at % of Ga and having an average particle size of 23.1 μm; and sintering the deoxidized Cu—Ga alloy powder under predetermined sintering conditions. FIG. 1 shows an image obtained by imaging a cross-section of the Cu—Ga alloy sputtering target using a scanning electron microscope (SEM). This image shows a state where micropores and macropores are present together in the target. When the sizes of the pores in the target were measured, the average diameter of circumscribed circles of the pores was 21 μm or less, and the porosity was 1.7%. When a sputtering test was performed using the Cu—Ga alloy sputtering target, during high-power DC sputtering, abnormal discharge was not generated, and stable sputtering was able to be performed.

On the other hand, in a comparative example of a Cu—Ga alloy sputtering target, base powder was prepared by mixing a predetermined amount of Cu—Ga alloy powder including 50.0 at % of Ga and having an average particle size of 60.0 μm with a predetermined amount of Cu powder having an average particle size of 25.1 μm. This base powder was sintered under predetermined sintering conditions without being reduced and deoxidized. As a result, the comparative example of the Cu—Ga alloy sputtering target was manufactured. FIG. 2 shows an image obtained by imaging a cross-section of the Cu—Ga alloy sputtering target using a scanning electron microscope (SEM). This image shows a state where pores having a visually recognizable size are present in the target. In the image of FIG. 2, micropores are not shown due to magnification. When the sizes of the pores in the target were measured, the average diameter of circumscribed circles of the pores was 1620 μm, and the porosity was 5.2%. When a sputtering test was performed using the Cu—Ga alloy sputtering target, even during low-power DC sputtering, abnormal discharge was generated frequently. In addition, during high-power DC sputtering, the target broke, and thus sputtering was not able to be performed.

Therefore, the present invention is obtained based on the above-described findings and adopts the following configurations in order to solve the above-described problems.

(1) According to an aspect of the present invention, a Cu—Ga alloy sputtering target which is a sintered body is provided, including, as a component composition, Ga: 0.1 to 40.0 at % and a balance including Cu and inevitable impurities, in which a porosity is 3.0% or lower, an average diameter of circumscribed circles of pores is 150 μm or less, and an average crystal grain size of Cu—Ga alloy particles is 50 μm or less.
(2) The sintered body as the Cu—Ga alloy sputtering target according to (1) further includes Na: 0.05 to 15.0 at %.
(3) In the Cu—Ga alloy sputtering target according to (2), Na is in the form of at least one Na compound among sodium fluoride, sodium sulfide, or sodium selenide.
(4) In the sintered body as the Cu—Ga alloy sputtering target according to (3), a structure in which the Na compound is dispersed in a Cu—Ga alloy matrix is present, and an average particle size of the Na compound is 10 μm or less.
(5) The sintered body as the Cu—Ga alloy sputtering target according to (1) further includes K: 0.05 to 15.0 at %.
(6) In the Cu—Ga alloy sputtering target according to (5), K is in the form of at least one K compound among potassium fluoride, potassium chloride, potassium bromide, potassium iodide, potassium sulfide, potassium selenide, or potassium niobate.
(7) In the sintered body as the Cu—Ga alloy sputtering target according to (6), a structure in which the K compound is dispersed in a Cu—Ga alloy matrix is present, and an average particle size of the K compound is 10 μm or less.
(8) According to another aspect of the present invention, a method for manufacturing a Cu—Ga alloy sputtering target is provided, the method including: a step of deoxidizing Cu—Ga alloy powder at 200° C. or higher in a reducing atmosphere, the Cu—Ga alloy powder including, as a component composition, Ga: 0.1 to 40.0 at % and a balance which includes Cu and inevitable impurities; and a step of sintering the deoxidized Cu—Ga alloy powder.
(9) According to still another aspect of the present invention a method for manufacturing a Cu—Ga alloy sputtering target is provided, the method comprising: a step of preparing base powder including Ga: 0.1 to 40.0 at % as a component composition by mixing Cu—Ga alloy powder having an average particle size of less than 50 μm with pure copper powder, the Cu—Ga alloy powder including, as a chemical composition, Ga: 10.0 to 75.0 at % and a balance which includes Cu and inevitable impurities; a step of deoxidizing the base powder at 200° C. or higher in a reducing atmosphere; and a step of sintering the deoxidized base powder.

### Advantageous Effects of Invention

The Cu—Ga alloy sputtering target according to the present invention is a Cu—Ga alloy sintered body including Ga: 0.1 to 40.0 at %, in which an average crystal grain size of Cu—Ga alloy particles is 50 μm or less, a porosity indicating the presence of pores is 3.0% or lower, and an average diameter of circumscribed circles of pores is 150 μm or less. As a result, the generation of abnormal discharge can be reduced during low-power DC sputtering, and the target does not break and the generation of abnormal discharge can be suppressed even during high-power DC sputtering. Further, even in a case where the Na compound or the K compound is added to the Cu—Ga alloy sputtering target, likewise, the target does not break and the generation of abnormal discharge can be suppressed.

In addition, in the manufacturing method according to the present invention, in either case of (8) or (9), the base powder is deoxidized before sintering. Therefore, the oxygen content in the base powder is reduced, the pores in the sintered body can be controlled, and the formation of large pores can be prevented. Thus, in the manufacturing method according to the present invention, the generation of abnormal discharge during high-power DC sputtering can be reduced, the target does not break, and stable sputtering can be performed.

### BRIEF DESCRIPTION OF DRAWINGS

FIG. 1 is an image obtained by imaging a cross-section of a Cu—Ga alloy sputtering target using a scanning electron microscope (SEM) as a specific example of a Cu—Ga alloy sputtering target according to Example of the present invention.

FIG. 2 is an image obtained by imaging a cross-section of a Cu—Ga alloy sputtering target using a scanning electron microscope (SEM) as a specific example of a Cu—Ga alloy sputtering target according to Comparative Example.

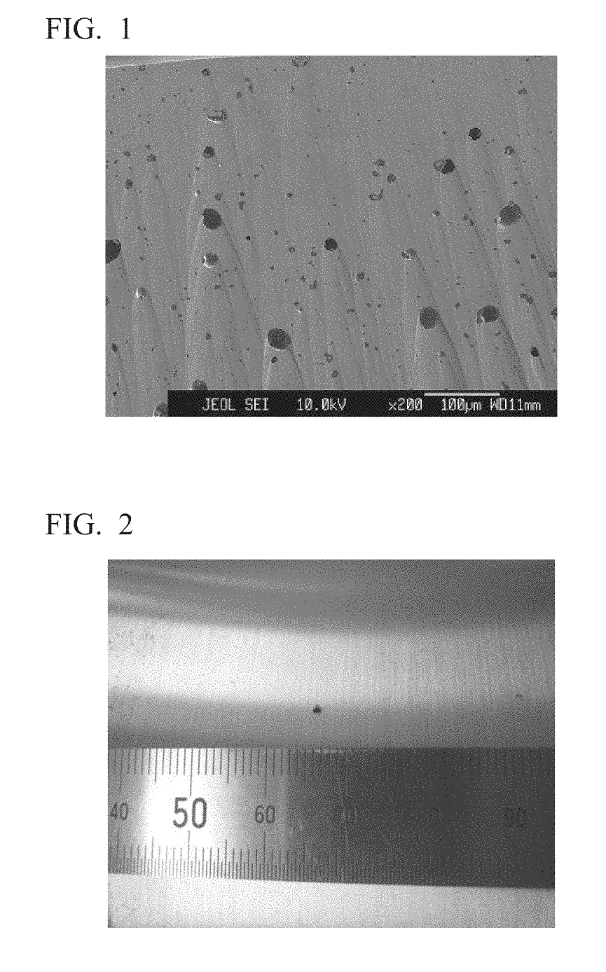

### BEST MODE FOR CARRYING OUT THE INVENTION

A Cu—Ga alloy sputtering target according to an embodiment of the present invention is a sintered body including, as a component composition, Ga: 0.1 to 40.0 at % and a balance which includes Cu and inevitable impurities, in which a porosity is 3.0% or lower, an average diameter of circumscribed circles of pores is 150 μm or less, and an average crystal grain size of Cu—Ga alloy particles is 50 μm or less. Here, regarding the shape and size of pores, in a case where the average diameter of the circumscribed circles of the pores is more than 150 μm, abnormal discharge is likely to be generated immediately after the start of sputtering. In addition, in a case where the average diameter of the circumscribed circles of the pores is in a range of 100 to 150 μm, abnormal discharge is likely to be generated along with the progress of sputtering. Therefore, it is preferable that the average diameter of the circumscribed circles of the pores be less than 100 μm. The lower limit of the average diameter of the circumscribed circles of the pores is generally 1 μm but, in the embodiment, is preferably 10 μm. The lower limit of the porosity is generally 0.1%. The porosity is preferably 0.1% to 2%, but the present invention is not limited thereto. In a case where the porosity is the above-described preferable value, the generation of abnormal discharge during high-power sputtering is avoidable. In a case where the Ga content is in a range of 0.1 to 40.0 at %, no single-phase Ga is deposited, abnormal discharge is not generated, and thus sputtering is stable. The Ga content is preferably 20 at % to 35 at %, but the present invention is not limited thereto.

In a case where a structure in which the average crystal grain size of the Cu—Ga alloy particles is more than 50 μm is present in the sintered body, when sputtering progresses to some extent, edges of Cu—Ga alloy crystals are exposed, and electrical charge is concentrated on these edges. Therefore, abnormal discharge is likely to be generated, and thus abnormal discharge is generated frequently. The lower limit of the average crystal grain size of the Cu—Ga alloy particles is generally 1 μm. In a case where a Na compound is added to the Cu—Ga alloy sputtering target, or in a case where a K compound is added to the Cu—Ga alloy sputtering target instead of the Na compound, the shape and size of the pores also relate to abnormal discharge. The average crystal grain size of the Cu—Ga alloy particles is preferably 5 μm to 30 μm, but the present invention is not limited thereto. In a case where the average crystal grain size of the Cu—Ga alloy particles is the above-described preferable value, when the sputtering progresses, the generation of abnormal discharge is avoidable.

The Cu—Ga alloy sputtering target according to the embodiment of the present invention may further include sodium (Na) or potassium (K).

Specifically, the Cu—Ga alloy sputtering target includes, as a component composition, metal components (excluding Se and Nb) which include Ga: 0.1 to 40.0 at % and Na: 0.05 to 15.0 at % and a balance which includes Cu and inevitable impurities. In a case where K is added instead of Na, the Cu—Ga alloy sputtering target includes K: 0.05 to 15.0 at %. The Na content is preferably 0.1 at % to 7 at % and the K content is preferably 0.1 at % to 7 at %, but the present invention is not limited thereto.

Further, Na is in the form of at least one Na compound among sodium fluoride (NaF), sodium sulfide (NaS), or sodium selenide (Na₂Se). The Na compound is dispersed in a matrix of the Cu—Ga alloy sputtering target, and the average particle size of the Na compound is 10 μm or less. The lower limit of the average particle size of the Na compound is generally 0.1 μm. The average particle size of the Na compound is preferably 0.5 μm to 5 μm, but the present invention is not limited thereto.

In a case where K is added to the Cu—Ga alloy sputtering target, K is in the form of at least one K compound among potassium fluoride (KF), potassium chloride (KCl), potassium bromide (KBr), potassium iodide (KI), potassium sulfide (K₂S), potassium selenide (K₂Se), or potassium niobate (KNbO₃). The K compound is dispersed in a matrix of the Cu—Ga alloy sputtering target, and the average particle size of the K compound is 10 μm or less. The lower limit of the average particle size of the K compound is generally 0.1 μm. The average particle size of the K compound is preferably 0.5 μm to 5 μm, but the present invention is not limited thereto.

It is known that, by adding Na or K, the power generation efficiency of a Cu—In—Ga—Se quaternary compound film used as a light-absorbing layer of a solar cell can be improved. As a method of adding Na or K to the Cu—In—Ga—Se quaternary alloy thin film, a method of adding Na or K to a Cu—Ga alloy sputtering target used for forming a Cu—Ga film is known. A Cu—Ga alloy sputtering target to which Na or K is added can be used to form a Cu—In—Ga—Se quaternary compound film to which Na or K is added.

A method for manufacturing a Cu—Ga alloy sputtering target according to an embodiment of the present invention includes: a step of deoxidizing Cu—Ga alloy powder as base powder at 200° C. or higher in a reducing atmosphere, the Cu—Ga alloy powder including, as a component composition, Ga: 0.1 to 40.0 at % and a balance which includes Cu and inevitable impurities; and a step of sintering the deoxidized Cu—Ga alloy powder. Alternatively, the method for manufacturing a Cu—Ga alloy sputtering target according to the embodiment of the present invention includes: a step of preparing base powder including Ga: 0.1 to 40.0 at % as a component composition by mixing Cu—Ga alloy powder having an average particle size of less than 50 μm with pure copper powder, the Cu—Ga alloy powder including, as a chemical composition, Ga: 10.0 to 75.0 at % and a balance which includes Cu and inevitable impurities; a step of deoxidizing the base powder at 200° C. or higher in a reducing atmosphere; and a step of sintering the deoxidized base powder. The lower limit of the average particle size of the Cu—Ga alloy powder is generally 1 μm.

In the manufacturing method according to the embodiment of the present invention, 1) a Cu—Ga alloy sputtering target including Ga: 0.1 to 40.0 at % as a component composition may be manufactured using Cu—Ga alloy powder as base powder; or 2) a Cu—Ga alloy sputtering target including Ga: 0.1 to 40.0 at % as a component composition may be manufactured using a mixture of Cu—Ga alloy powder and pure copper powder as base powder. In either case of 1) or 2), the base powder is deoxidized before sintering. This deoxidizing treatment is performed in a reducing atmosphere at a temperature of 200° C. or higher and (a melting point of the Cu—Ga alloy—100° C.) or lower. Due to this treatment, the oxygen content is reduced, the pores in the sintered body can be controlled, and the formation of large pores can be suppressed. Therefore, the generation of abnormal discharge can be reduced during high-power DC sputtering. In a case where two or more stages are provided as treatment conditions in the deoxidizing step, the formation of large pores can be further suppressed. In a manufacturing method in which two or more stages are set as treatment conditions in the deoxidizing step, for example, the base powder is deoxidized in a reducing atmosphere at a temperature of higher than that the previous stage of the deoxidizing step and (a melting point of the Cu—Ga alloy—100° C.) or lower. As a reducing atmosphere gas used in the deoxidizing step, a reducing gas such as hydrogen (H₂), carbon monoxide (CO), or ammonia cracking gas, or a mixed gas of the reducing gas and inert gas can be used. The lower limit of the temperature of the deoxidizing step is 200° C., and the upper limit thereof is 600° C. The temperature of the deoxidizing step is preferably 400° C. to 600° C., but the present invention is not limited thereto. Regarding the concentration of the reducing atmosphere gas in the deoxidizing step, the concentration of hydrogen is 10% to 20% or 75% to 100%, and the concentration of carbon monoxide is 70% to 100%. The concentration of hydrogen may be 80% to 100%, and the concentration of carbon monoxide may be 80% to 100%. The lower limit of the holding time in the deoxidizing step is 5 hours, and the upper limit thereof is 30 hours. The holding time in the deoxidizing step may be 10 hours to 25 hours.

As a treatment method in the sintering step, pressureless sintering or hot pressing can be used. The lower limit of the temperature in the sintering step is 600° C., and the upper limit thereof is 900° C. The temperature in the sintering step may be 700° C. to 800° C. The lower limit of the holding time in the sintering step is 2 hours, and the upper limit thereof is 15 hours. The holding time in the sintering step may be 2 hours to 10 hours. The lower limit of the pressure in the sintering step is 10 MPa, and the upper limit thereof is 30 MPa. The pressure in the sintering step may be 15 MPa to 30 MPa. In the sintering step, an atmosphere may be hydrogen (H₂), carbon monoxide (CO), argon (Ar), or a vacuum. Regarding the concentration of the atmosphere gas in the sintering step, the concentration of hydrogen may be 80% to 100%, and the concentration of carbon monoxide may be 80% to 100%.

Further, in either case of 1) or 2), Na or K can be added to the Cu—Ga alloy sputtering target. Na or K can be added by mixing the Na compound powder or the K compound powder with the base powder. By controlling the average particle size of the Cu—Ga alloy powder, which includes, as a component composition, Ga: 10.0 to 75.0 at % and a balance including Cu and inevitable impurities, to be less than 50 μm, the average particle size of the Cu—Ga alloy in the target structure can be reduced to be less than 50 μm, and Therefore, the generation of abnormal discharge can be reduced during high-power sputtering.

### EXAMPLES

Next, the Cu—Ga alloy sputtering target according to the present invention will be described below in more detail using Examples.

### Example

First, Cu—Ga alloy powder and pure copper powder were prepared in order to prepare the Cu—Ga alloy sputtering target according to the present invention. The Cu—Ga alloy powder was prepared using a gas atomization method after weighing Cu ingot and Ga ingot such that the Ga content was as shown in Table 1, and melting the Cu ingot and the Ga ingot in a crucible. In Examples 1 and 2, the Cu—Ga alloy powder was used as base powder. In Examples 3, 4, and 8 to 12, mixed powder obtained by mixing the Cu—Ga alloy powder with pure copper powder at a mixing ratio shown in Table 1 was used as base powder. During the mixing in a rocking mixer, the rotating speed was 72 rpm and the mixing time was 30 minutes. In addition, in Examples 5 to 7, a Na compound was added at a mixing ratio shown in Table 1, and 3N (purity 99.9%) Na compound powder was prepared. In Examples 5 and 6, base powder was prepared by mixing the Cu—Ga alloy powder, pure copper powder, and the Na compound powder with each other using a rocking mixer. In Example 7, base powder was prepared by mixing the Cu—Ga alloy powder and the Na compound powder with each other using a rocking mixer. In Examples 13 to 19, base powder was prepared by mixing the Cu—Ga alloy powder, K compound powder, and pure copper powder (except for Examples 16, 18, and 19) with each other using a rocking mixer. The average particle sizes of the Cu—Ga alloy powder, the pure copper powder, the Na compound powder, and the K compound powder used in the base powders were measured, and the results are as shown in “Average particle Size (μm)” in Table 1.

The average particle size of each of the Cu—Ga alloy powder and the pure copper powder was obtained by preparing an aqueous solution including 0.2% of sodium hexametaphosphate, adding an appropriate amount of the powder to the aqueous solution, and measuring a particle size distribution of the alloy powder using Microtrac MT3000 (manufactured by Nikkiso Co., Ltd.).

In addition, the average particle size of each of the Na compound powder and the K compound powder was measured based on an image obtained by imaging the powder using a SEM. Maximum sizes of 50 or more arbitrary particles present in the SEM image were measured, and the average value of the particle sizes was calculated. The maximum size of each particle refers to a value of diameters of a maximum circumscribed circle which was drawn in contact with the particle. These treatments were performed on three SEM images, and the average value was obtained as the average particle size. In addition, in a case where the Na compound powder and the K compound powder were hygroscopic, a sample was set in a glove box filled with inert gas and then the glove box was covered with a film for a vacuum so as to prevent contact with air.

Next, 1200 of 2000 g of each of the base powders prepared as described above was weighed, was put into a carbon crucible, and then was reduced in a reducing atmosphere furnace under deoxidizing conditions shown in Table 2 to reduce the oxygen (O) content. As reducing conditions, the concentration of hydrogen was 10% to 20% (the balance was nitrogen) or 75% to 100% (the balance was nitrogen), or the concentration of carbon monoxide was 70% to 100% (the balance was nitrogen); the temperature was 200° C. to 600° C.; and the holding time was 5 to 30 hours. Next, the reduced base powder was put into a carbon mold and was sintered under a pressure of 10 to 30 MPa at a temperature of 600° C. to 900° C. for a holding time of 2 to 15 hours. At this time, the reducing step and the sintering step may be continuously performed. In the pressureless sintering, a molded article obtained by pressing was reduced and sintered. At this time, the reduced powder may be pressed and sintered. By sintering the powder under sintering conditions shown in Table 2, Cu—Ga alloy sintered bodies according to Examples 1 to 19 were obtained. By turning surface portions and peripheral portions of the obtained sintered bodies, sputtering targets according to Examples 1 to 19 having a diameter of 152.4 mm and a thickness of 6 mm were prepared.

### Comparative Examples

For comparison with the above-described Examples, Cu—Ga alloy sputtering targets according to Comparative Examples 1 to 13 were prepared. As in the case of Examples 1 and 2, Cu—Ga alloy sputtering targets according to Comparative Examples 1 and 3 were prepared by using the Cu—Ga alloy powder as base powder. As in the case of Example 3 and the like, Cu—Ga alloy sputtering targets according to Comparative Examples 2, 4, 7 to 10, and 13 were prepared by using mixed powder, which was obtained by mixing the Cu—Ga alloy powder and pure copper powder with each other at a mixing ratio shown in Table 1, as base powder. As in the case of Examples 5 and 6, Cu—Ga alloy sputtering targets according to Comparative Examples 5 and 6 were prepared by using mixed powder to which a Na compound was added at a mixing ratio shown in Table 1, as base powder. Further, a Cu—Ga alloy sputtering target according to Comparative Example 11 was prepared using bulk materials including Cu: 75 at % and Ga: 25 at % at a composition ratio. A Cu—Ga alloy sputtering target according to Comparative Example 12 was prepared with a casting method using bulk materials including Cu: 70 at % and Ga: 30 at % at a composition ratio. In Comparative Examples 1, 2, and 9 to 12, the reducing treatment was not performed. In Comparative Example 13, mixed powder of Cu—Ga alloy powder having an average particle size of 100 μm or more and pure copper powder was used as base powder. As in the case of Examples 1 to 19, in Comparative Example 13, the base powder was reduced and sintered.

TABLE 1

| | Base Powder | | | | | | | |
|---|---|---|---|---|---|---|---|---|
| | Cu—Ga Powder | | | Cu Powder | | Na or K Compound Powder | | |
| | Ga | Average | Mixing | Average | Mixing | | Average | Mixing |
| | Content | Particle Size | Ratio | Particle Size | Ratio | Na or K | Particle Size | Ratio |
| | (at %) | (μm) | (%) | (μm) | (%) | Compound | (μm) | (%) |
| Example 1 | 35 | 23.1 | 100 | — | — | — | — | — |
| Example 2 | 25 | 34.6 | 100 | — | — | — | — | — |
| Example 3 | 40 | 14.3 | 75 | 25.1 | 25 | — | — | — |
| Example 4 | 50 | 21.8 | 40 | 50.3 | 60 | — | — | — |
| Example 5 | 60 | 19.7 | 41.7 | 25.1 | 56.3 | NaF | 6.8 | 2 |
| Example 6 | 50 | 24.5 | 60 | 50.3 | 35.5 | Na₂S | 8.7 | 4.5 |
| Example 7 | 25 | 34.6 | 86.4 | — | — | Na₂Sc | 10.3 | 13.6 |
| Example 8 | 60 | 19.7 | 50 | 25.1 | 50 | — | — | — |
| Example 9 | 40 | 14.3 | 75 | 25.1 | 25 | — | — | — |
| Example 10 | 50 | 21.8 | 40 | 50.3 | 60 | — | — | — |
| Example 11 | 50 | 21.8 | 20 | 25.1 | 80 | — | — | — |
| Example 12 | 50 | 21.8 | 80 | 50.3 | 20 | — | — | — |
| Example 13 | 60 | 19.7 | 50 | 50.3 | 48 | KF | 9.6 | 2 |
| Example 14 | 50 | 21.8 | 70 | 25.1 | 27.1 | KCl | 5.4 | 2.9 |
| Example 15 | 60 | 19.7 | 41.6 | 50.3 | 55.3 | KBr | 3.8 | 3.1 |
| Example 16 | 25 | 34.6 | 97.9 | — | — | KI | 7.6 | 2.1 |
| Example 17 | 60 | 19.7 | 41.7 | 25.1 | 55.5 | K₂S | 8.3 | 2.8 |
| Example 18 | 35 | 23.1 | 99 | — | — | K₂Se | 6.8 | 1 |
| Example 19 | 25 | 34.6 | 95.4 | — | — | KNbO₃ | 9.7 | 4.6 |
| Comparative | 25 | 34.6 | 100 | — | — | — | — | — |
| Example 1 | | | | | | | | |
| Comparative | 50 | 24.5 | 60 | 25.1 | 40 | — | — | — |
| Example 2 | | | | | | | | |
| Comparative | 25 | 34.6 | 100 | — | — | — | — | — |
| Example 3 | | | | | | | | |
| Comparative | 60 | 19.7 | 58.3 | 25.1 | 41.7 | — | — | — |
| Example 4 | | | | | | | | |
| Comparative | 50 | 24.5 | 60 | 25.1 | 36 | NaF | 6.8 | 4 |
| Example 5 | | | | | | | | |
| Comparative | 60 | 19.7 | 41.7 | 14.6 | 52.3 | Na₂S | 24.3 | 6 |
| Example 6 | | | | | | | | |
| Comparative | 60 | 60.7 | 50 | 50.3 | 50 | — | — | — |
| Example 7 | | | | | | | | |
| Comparative | 40 | 52.1 | 75 | 50.3 | 25 | — | — | — |
| Example 8 | | | | | | | | |
| Comparative | 50 | 45.7 | 60 | 25.1 | 40 | — | — | — |
| Example 9 | | | | | | | | |
| Comparative | 60 | 49.3 | 41.7 | 14.6 | 58.3 | — | — | — |
| Example 10 | | | | | | | | |
| Comparative | Bulk Material Cu: 75 at %, Ga: 25 at % | | | | | — | — | — |
| Example 11 | | | | | | | | |
| Comparative | Bulk Material Cu: 70 at %, Ga: 30 at % | | | | | — | — | — |
| Example 12 | | | | | | | | |
| Comparative | 40 | 102.5 | 75 | 126.8 | 25 | — | — | — |
| Example 13 | | | | | | | | |

TABLE 2

| | Manufacturing Method | | | | | | | |
|---|---|---|---|---|---|---|---|---|
| | Deoxidizing Conditions | | | | Sintering Conditions | | | |
| | Treatment | | Temperature | Time | Treatment | | Temperature | Time |
| | Method | Atmosphere | (° C.) | (h) | Method | Atmosphere | (° C.) | (h) |
| Example 1 | Reducing | H₂ 80% | 400 | 25 | Pressureless | H₂ 100% | 650 | 10 |
| | Furnace | | | | Sintering | | | |
| Example 2 | Reducing | CO 100% | 450 | 15 | Hot Pressing | Vacuum | 780 | 3 |
| | Furnace | | | | | | | |
| Example 3 | Reducing | CO 90% | 300 | 5 | Pressureless | H₂ 75% | 780 | 7 |
| | Furnace | | | | Sintering | | | |
| Example 4 | Reducing | H₂ 100% | 250 | 5 | Pressureless | CO 100% | 850 | 10 |
| | Furnace | | | | Sintering | | | |
| Example 5 | Reducing | H₂ 75% | 400 | 20 | Pressureless | H₂ 80% | 800 | 5 |
| | Furnace | | | | Sintering | | | |
| Example 6 | Reducing | H₂ 80% | 200 | 10 | Pressureless | CO 100% | 760 | 3 |
| | Furnace | | | | Sintering | | | |
| Example 7 | Reducing | CO 90% | 400 | 30 | Hot Pressing | Vacuum | 780 | 2 |
| | Furnace | | | | | | | |
| Example 8 | Reducing | H₂ 20% | 600 | 15 | Pressureless | H₂ 100% | 780 | 5 |
| | Furnace | | | | Sintering | | | |
| Example 9 | Reducing | H₂ 80% | 400 | 15 | Pressureless | H₂ 80% | 800 | 10 |
| | Furnace | | | | Sintering | | | |
| Example 10 | Reducing | CO 100% | 400 | 15 | Hot Pressing | Vacuum | 850 | 5 |
| | Furnace | | | | | | | |
| Example 11 | Reducing | H₂ 15% | 550 | 10 | Pressureless | H₂ 80% | 900 | 5 |
| | Furnace | | | | Sintering | | | |
| Example 12 | Reducing | H₂ 20% | 500 | 20 | Hot Pressing | Vacuum | 600 | 3 |
| | Furnace | | | | | | | |
| Example 13 | Reducing | H₂ 80% | 550 | 10 | Hot Pressing | Vacuum | 750 | 2 |
| | Furnace | | | | | | | |
| Example 14 | Reducing | H₂ 10% | 600 | 10 | Hot Pressing | Vacuum | 700 | 3 |
| | Furnace | | | | | | | |
| Example 15 | Reducing | CO 100% | 500 | 5 | Pressureless | H₂ 100% | 750 | 10 |
| | Furnace | | | | Sintering | | | |
| Example 16 | Reducing | CO 70% | 450 | 15 | Hot Pressing | Vacuum | 750 | 2 |
| | Furnace | | | | | | | |
| Example 17 | Reducing | H₂ 80% | 550 | 20 | Pressureless | CO 90% | 780 | 15 |
| | Furnace | | | | Sintering | | | |
| Example 18 | Reducing | H₂ 100% | 600 | 10 | Pressureless | H₂ 80% | 750 | 10 |
| | Furnace | | | | Sintering | | | |
| Example 19 | Reducing | CO 90% | 500 | 20 | Hot Pressing | Ar | 800 | 2 |
| | Furnace | | | | | | | |
| Comparative | None | | | | Hot Pressing | Vacuum | 780 | 2 |
| Example 1 | | | | | | | | |
| Comparative | None | | | | Pressureless | CO 90% | 750 | 10 |
| Example 2 | | | | | Sintering | | | |
| Comparative | Reducing | CO 100% | 150 | 20 | Pressureless | H₂ 75% | 750 | 10 |
| Example 3 | Furnace | | | | Sintering | | | |
| Comparative | Reducing | H₂ 75% | 100 | 25 | Hot Pressing | Vacuum | 670 | 3 |
| Example 4 | Furnace | | | | | | | |
| Comparative | Reducing | H₂ 100% | 150 | 15 | Pressureless | CO 90% | 750 | 5 |
| Example 5 | Furnace | | | | Sintering | | | |
| Comparative | Reducing | CO 100% | 150 | 20 | Pressureless | H₂ 100% | 800 | 7 |
| Example 6 | Furnace | | | | Sintering | | | |
| Comparative | Reducing | H₂ 80% | 600 | 15 | Pressureless | H₂ 100% | 780 | 20 |
| Example 7 | Furnace | | | | Sintering | | | |
| Comparative | Reducing | H₂ 80% | 400 | 15 | Hot Pressing | Vacuum | 800 | 10 |
| Example 8 | Furnace | | | | | | | |
| Comparative | None | | | | Pressureless | H₂ | 780 | 10 |
| Example 9 | | | | | Sintering | | | |
| Comparative | None | | | | Hot Pressing | Vacuum | 800 | 5 |
| Example 10 | | | | | | | | |
| Comparative | None | | | | Casting | | | |
| Example 11 | | | | | | | | |
| Comparative | None | | | | Casting | | | |
| Example 12 | | | | | | | | |
| Comparative | Reducing | H₂ 100% | 600 | 20 | Pressureless | Vacuum | 810 | 10 |
| Example 13 | Furnace | | | | Sintering | | | |

Next, as target characteristics relating to the Cu—Ga alloy sputtering targets according to Examples 1 to 19 and Comparative Examples 1 to 13 prepared as described above, the composition of target metal components, the average diameter of circumscribed circles of pores, the porosity, the average crystal grain size of Cu—Ga alloy particles, and the average particle size of the Na compound or the K compound were measured. Further, during sputtering film formation using each of the Cu—Ga alloy sputtering targets according to Examples 1 to 19 and Comparative Examples 1 to 13, the sputtering characteristics were measured.

### <Analysis of Target Metal Components>

By performing quantitative analysis using an ICP spectrometer 725-ES (manufactured by Agilent Technologies Inc.), the concentrations of Ga, Na, and K were measured.

The measurement results are shown in the item “Composition (at %) of Metal Components” of Table 3. The density of Cu was calculated based on the analysis results of Ga, Na, and K and is expressed as “Balance”.

### <Measurement of Average Diameter of Circumscribed Circles of Pores>

A fragment of each of the prepared sputtering targets according to Examples and Comparative Examples was treated by cross-section polishing (CP) to expose a surface thereof, and the obtained surface was observed with a SEM. The magnification of the SEM image was appropriately adopted according to the crystal grain size. A circumscribed circle of a pore observed in the SEM image was drawn such that the diameter thereof was maximum. At this time, the diameter of the circumscribed circle was obtained as the size of the pore. By performing this operation on all of the pores observed in the SEM image, the average value of the obtained values was obtained as the pore size in the single SEM image. The average value of pore sizes of three SEM images obtained as described above was obtained.

The measurement results are shown in the item “Average Diameter (μm) of Circumscribed Circles of Pores” of Table 3. The size of the SEM image was set as at least 400×500 μm.

### <Measurement of Porosity>

The SEM image obtained by the same operation as in the measurement of the diameters of the circumscribed circles was converted into a monochrome image using a commercially available image analysis software, and the monochrome image was binarized using a single threshold. Due to this treatment, the pore portions were shown as dark regions. As the image analysis software, for example, WinRoof Ver. 5.6.2 (manufactured by Mitani Corporation) was used. The proportion of the area of the dark regions in the obtained image was obtained as a porosity.

The measurement results are shown in the item “Porosity (%)” of Table 3.

### <Measurement of Average Crystal Grain Size of Cu—Ga Alloy Particles>

The average crystal grain size of Cu—Ga alloy particles was measured using a planimetric method. A surface (turned surface) of each of the prepared sputtering targets according to Examples and Comparative Examples was etched with nitric acid for about 1 minute and was washed with pure water. Next, five arbitrary positions of the surface were observed using an optical microscope. Here, in a case where a clear structure was not observed, the surface was additionally etched with nitric acid. The obtained surface was imaged using a SEM at a magnification of 1000 times. Next, a circle whose area was known, for example, a circle having a diameter of about 100 μm was drawn on the obtained image, and the number (N_{c}) of particles present in the circle and the number (Nⱼ) of particles present on a circumference of the circle were measured. Based on the following expressions, the average crystal grain size was calculated, and the average value of the particle sizes at the five positions was obtained.

Average Crystal Grain Size=1/(N_{g})^{1/2}

Number of Particles N_{g} Per Unit Area=[N_{c}+(½)×Nⱼ]/(A/M²)

A: the area of the circle

N_{c}: the number of particles present in the circle

Nⱼ: the number of particles present on the circumference of the circle

M: a measure magnification of the SEM

The measurement results are shown in the item “Average Crystal Grain Size (μm) of Cu—Ga Alloy Particles” of Table 3.

### <Measurement of Average Particle Size of Na Compound or K Compound>

In order to measure the average particle size of the Na compound or the K compound, the obtained CP-treated surface of each of the sputtering targets according to Examples and Comparative Examples was imaged using an electron probe X-ray microanalyzer JXA-8500F (EPMA; manufactured by JEOL. Ltd.) at 500 times to obtain ten elemental mapping images (60 μm×80 μm) of each of Na and K. From the ten images, particle sizes of the Na compound or the K compound were measured, and the average particle size was calculated.

The measurement results are shown in the item “Average Particle Size (μm) of Na Compound or K Compound” of Table 3.

Regarding the sputtering characteristics which were measured during sputtering film formation using each of the Cu—Ga alloy sputtering targets according to Examples 1 to 19 and Comparative Examples 1 to 13, the number of times of abnormal discharge generated during the sputtering was measured separately in three different cases: low-power DC sputtering; high-power DC sputtering; and high-power DC sputtering after sputtering at 50 kWh. Here, each of the obtained sputtering targets was turned or cut in a shape having a diameter of 152.4 mm and a thickness of 6 mm and then was bonded to a back plate using a soldering material.

### (Conditions of Low-Power DC Sputtering)

Conditions of the low-power DC sputtering were as follows.

Tower: DC 1000 W

Total pressure: 0.6 Pa

Sputtering gas: Ar=30 sccm

### (Conditions of High-Power DC Sputtering)

The power was higher than that in the case of low-power DC sputtering, and conditions of the high-power DC sputtering are as follows.

Tower: DC 2000 W

Total pressure: 0.6 Pa

Sputtering gas: Ar=30 sccm

(Conditions of High-Power DC Sputtering after Sputtering at 50 kWh)

Regarding conditions of the high-power DC sputtering after sputtering at 50 kWh, high-power DC sputtering was performed after performing low-power DC sputtering at 50 kWh. The low-power DC sputtering was evaluated under the above-described conditions of the low-power DC sputtering, and the high-power DC sputtering was evaluated under the above-described conditions of the high-power DC sputtering.

### <Measurement of Number of Times of Abnormal Discharge>

Sputtering was performed under the above-described sputtering conditions for 10 minutes, and the number of times of abnormal discharge was measured using an arc counting function of a DC power supply. As the DC power supply, for example, RPG-50 (manufactured by MKS Instruments) was used.

The measurement results are shown in the item “Number of Times of Abnormal Discharge (times/10 min) in Low-Power Sputtering”, “Number of Times of Abnormal Discharge (times/10 min) in High-Power Sputtering”, and “Number of Times of Abnormal Discharge (times/10 min) in High-Power Sputtering after Sputtering at 50 kWh” of Table 4.

TABLE 3

| | Target Characteristics | | | | | | |
|---|---|---|---|---|---|---|---|
| | Composition (at %) of Metal | | | | | | |
| | Components | | | | | Average Crystal | Average Particle Size |
| | | Na | Cu and | Average Diameter (μm) | | Gram Size (μm) of | (μm) of Na |
| | | or | Inevitable | of Circumscribed | Porosity | Cu—Ga Alloy | Compound or K |
| | Ga | K | Impurities | Circles of Pores | (%) | Particles | Compound |
| Example 1 | 35 | — | Balance | 21 | 1.7 | 5.7 | — |
| Example 2 | 25 | — | Balance | 15 | 1.3 | 13.4 | — |
| Example 3 | 30 | — | Balance | 91 | 2.4 | 3.6 | — |
| Example 4 | 20 | — | Balance | 146 | 2.7 | 23.1 | — |
| Example 5 | 25 | 1 | Balance | 32 | 2.1 | 32.7 | 4.2 |
| Example 6 | 30 | 3 | Balance | 137 | 2.5 | 8.4 | 7.4 |
| Example 7 | 21.6 | 5 | Balance | 47 | 2.1 | 6.9 | 8.4 |
| Example 8 | 30 | — | Balance | 17 | 1.8 | 15.7 | — |
| Example 9 | 30 | — | Balance | 25 | 2.1 | 47.1 | — |
| Example 10 | 20 | — | Balance | 18 | 1.6 | 44.7 | — |
| Example 11 | 10 | — | Balance | 18 | 1.9 | 25.7 | — |
| Example 12 | 40 | — | Balance | 24 | 2.3 | 31.2 | — |
| Example 13 | 30 | 1 | Balance | 13 | 1.4 | 27.6 | 8.4 |
| Example 14 | 35 | 1.5 | Balance | 14 | 1.5 | 18.5 | 6.7 |
| Example 15 | 25 | 1 | Balance | 21 | 1.8 | 14.5 | 4.7 |
| Example 16 | 24.5 | 0.5 | Balance | 19 | 1.8 | 35.1 | 8.6 |
| Example 17 | 25 | 2 | Balance | 17 | 1.6 | 16.7 | 8.9 |
| Example 18 | 34.7 | 0.5 | Balance | 15 | 1.4 | 25.7 | 7.8 |
| Example 19 | 23.9 | 1 | Balance | 22 | 2.2 | 37.8 | 9.9 |
| Comparative | 25 | — | Balance | 170 | 3.1 | 8.5 | — |
| Example 1 | | | | | | | |
| Comparative | 30 | — | Balance | 1620 | 5.2 | 9.4 | — |
| Example 2 | | | | | | | |
| Comparative | 25 | — | Balance | 257 | 4.3 | 12.4 | — |
| Example 3 | | | | | | | |
| Comparative | 35 | — | Balance | 189 | 3.2 | 14.8 | — |
| Example 4 | | | | | | | |
| Comparative | 30 | 2 | Balance | 210 | 3.8 | 21.7 | 5.4 |
| Example 5 | | | | | | | |
| Comparative | 25 | 4 | Balance | 242 | 4.1 | 7.8 | 19.8 |
| Example 6 | | | | | | | |
| Comparative | 30 | — | Balance | 27 | 2.3 | 62.1 | — |
| Example 7 | | | | | | | |
| Comparative | 30 | — | Balance | 18 | 1.8 | 52.9 | — |
| Example 8 | | | | | | | |
| Comparative | 30 | — | Balance | 256 | 1.7 | 47.8 | — |
| Example 9 | | | | | | | |
| Comparative | 25 | — | Balance | 26 | 4.4 | 49.1 | — |
| Example 10 | | | | | | | |
| Comparative | 25 | — | Balance | 31 | <0.1 | 2564 | — |
| Example 11 | | | | | | | |
| Comparative | 30 | — | Balance | 22 | 0.1 | 3452 | — |
| Example 12 | | | | | | | |
| Comparative | 30 | — | Balance | 195.6 | 0.9 | 116.4 | — |
| Example 13 | | | | | | | |

TABLE 4

| | Sputtering Characteristics | | |
|---|---|---|---|
| | | | Number of Times of |
| | Number of Times | Number of Times | Abnormal Discharge |
| | of Abnormal | of Abnormal | (times/10 min) in |
| | Discharge | Discharge | High-Power |
| | (times/10 min) in | (times/10 min) in | Sputtering after |
| | Low-Power | High-Power | Sputtering |
| | Sputtering | Sputtering | at 50 kWh |
| Example 1 | 0 | 0 | 0 |
| Example 2 | 0 | 0 | 1 |
| Example 3 | 0 | 10 | 35 |
| Example 4 | 0 | 28 | 43 |
| Example 5 | 0 | 7 | 13 |
| Example 6 | 1 | 13 | 19 |
| Example 7 | 2 | 21 | 32 |
| Example 8 | 0 | 0 | 0 |
| Example 9 | 0 | 3 | 20 |
| Example 10 | 0 | 1 | 13 |
| Example 11 | 0 | 0 | 2 |
| Example 12 | 1 | 2 | 6 |
| Example 13 | 1 | 13 | 21 |
| Example 14 | 0 | 10 | 11 |
| Example 15 | 0 | 8 | 10 |
| Example 16 | 1 | 11 | 21 |
| Example 17 | 1 | 12 | 19 |
| Example 18 | 0 | 12 | 14 |
| Example 19 | 2 | 14 | 27 |
| Comparative | 2 | 436 | 3146 |
| Example 1 | | | |
| Comparative | 458 | Broke During | Broke During |
| | | Sputtering | Sputtering |
| Example 2 | | | |
| Comparative | 6 | 436 | 3123 |
| Example 3 | | | |
| Comparative | 4 | 341 | 4313 |
| Example 4 | | | |
| Comparative | 7 | 529 | 4566 |
| Example 5 | | | |
| Comparative | 124 | 1351 | Broke During |
| | | | Sputtering |
| Example 6 | | | |
| Comparative | 0 | 3 | 115 |
| Example 7 | | | |
| Comparative | 1 | 5 | 128 |
| Example 8 | | | |
| Comparative | 7 | 321 | 623 |
| Example 9 | | | |
| Comparative | 1 | 121 | 324 |
| Example 10 | | | |
| Comparative | 0 | 5 | 7431 |
| Example 11 | | | |
| Comparative | 0 | 14 | Broke During |
| | | | Sputtering |
| Example 12 | | | |
| Comparative | 5 | 117 | 458 |
| Example 13 | | | |

It was verified from the above results that, in all the Cu—Ga alloy sputtering targets according to Examples 1 to 19, the porosity was 3.0% or lower, the average diameter of circumscribed circles of pores was 150 μm or less, and the average crystal grain size of Cu—Ga alloy particles was 50 μm or less. In addition, it was found that, even in a case where micropores and macropores are present together in a sputtering target, as long as the size of the macropores is 150 μm or less, the following effects can be obtained: the generation of abnormal discharge can be sufficiently reduced during high-power DC sputtering; and even in a case where high-power DC sputtering is continuously performed or a case where high-power DC sputtering is performed after low-power DC sputtering, the generation of abnormal discharge can be suppressed, and stable sputtering can be performed.

On the other hand, in Comparative Examples 1, 3 to 5, 9, 10, and 13, the frequency of abnormal discharge was low in the case of the low-power DC sputtering; however, abnormal discharge was generated frequently in the case of the high-power DC sputtering, and abnormal discharge was generated more frequently in the case of the high-power DC sputtering after sputtering at 50 kWh. As a result, stable sputtering was not able to be performed. In addition, in Comparative Example 2, abnormal discharge was generated frequently even in the case of the low-power DC sputtering, and the target broke during sputtering in the case of the high-power DC sputtering. In Comparative Example 6, abnormal discharge was generated frequently even in the case of the low-power DC sputtering, abnormal discharge was generated more frequently in the case of the high-power DC sputtering, and the target broke during sputtering in the case of the high-power DC sputtering after sputtering at 50 kWh. In Comparative Examples 7, 8, and 11, the frequency of abnormal discharge was low in the case of the low-power DC sputtering and in the case of the high-power DC sputtering; however, abnormal discharge was generated frequently in the case of the high-power DC sputtering after sputtering at 50 kWh. As a result, stable sputtering was not able to be performed. In Comparative Example 12, the target broke in the case of the high-power DC sputtering after sputtering at 50 kWh. In the Cu—Ga alloy sputtering target according to Comparative Example 13, the porosity was 1% or lower, and the average diameter of circumscribed circles of pores was more than 150 μm. The reason why the porosity of the Cu—Ga alloy sputtering target was 1% or lower is that the Cu—Ga alloy sputtering target was manufactured by reducing and sintering the base powder as in the case of Examples 1 to 19. The reason why the average diameter of circumscribed circles of pores was more than 150 μm is that, since the mixed powder of the Cu—Ga alloy powder having an average particle size of 100 μm or more and pure copper powder was used as the base powder, the average crystal grain size of the Cu—Ga alloy particles obtained by sintering was large, and the size of pores formed in the boundaries between the Cu—Ga alloy particles was large. It was found from the result of Comparative Example 13 that, even in a case where the porosity of a Cu—Ga alloy sputtering target is 1.0% or lower, as long as macropores are present in the sputtering target, high-power sputtering cannot be stably performed.

As described above, the Cu—Ga alloy sputtering target according to the present invention is a Cu—Ga alloy sintered body including Ga: 0.1 to 40.0 at %, in which an average crystal grain size of Cu—Ga alloy particles is 50 μm or less, a porosity indicating the presence of pores is 3.0% or lower, and an average diameter of circumscribed circles of pores is 150 μm or less. As a result, it was verified that the generation of abnormal discharge can be reduced during low-power DC sputtering, and the target does not break and the generation of abnormal discharge can be suppressed even during high-power DC sputtering. Further, it was also verified that even in a case where the Na compound or the K compound is added to the Cu—Ga alloy sputtering target, the same effects can be obtained.

### INDUSTRIAL APPLICABILITY

With the Cu—Ga alloy sputtering target according to the present invention, even during high-power sputtering, the generation of splashing or abnormal discharge can be suppressed, and stable sputtering can be performed. The Cu—Ga alloy sputtering target according to the present invention is suitable for use in forming a Cu—In—Ga—Se compound film which is used as a light-absorbing layer of a thin-film solar cell.

1. A Cu—Ga alloy sputtering target comprising, as a component composition,
Ga: 0.1 to 40.0 at %, and
a balance including Cu and inevitable impurities,
wherein a porosity is 3.0% or lower,
an average diameter of circumscribed circles of pores is 150 μm or less, and
an average crystal grain size of Cu—Ga alloy particles is 50 μm or less.

2. The Cu—Ga alloy sputtering target according to claim 1, further comprising
Na: 0.05 to 15.0 at %.

3. The Cu—Ga alloy sputtering target according to claim 2,
wherein Na is in the form of at least one Na compound among sodium fluoride, sodium sulfide, or sodium selenide.

4. The Cu—Ga alloy sputtering target according to claim 3,
wherein a structure in which the Na compound is dispersed in a Cu—Ga alloy matrix is present, and
an average particle size of the Na compound is 10 μm or less.

5. The Cu—Ga alloy sputtering target according to claim 1, further comprising
K: 0.05 to 15.0 at %.

6. The Cu—Ga alloy sputtering target according to claim 5,
wherein K is in the form of at least one K compound among potassium fluoride, potassium chloride, potassium bromide, potassium iodide, potassium sulfide, potassium selenide, or potassium niobate.

7. The Cu—Ga alloy sputtering target according to claim 6,
wherein a structure in which the K compound is dispersed in a Cu—Ga alloy matrix is present, and
an average particle size of the K compound is 10 μm or less.

8. A method for manufacturing a Cu—Ga alloy sputtering target, the method comprising:
a step of deoxidizing Cu—Ga alloy powder at 200° C. or higher in a reducing atmosphere, the Cu—Ga alloy powder including, as a component composition, Ga: 0.1 to 40.0 at % and a balance which includes Cu and inevitable impurities; and
a step of sintering the deoxidized Cu—Ga alloy powder.

9. A method for manufacturing a Cu—Ga alloy sputtering target, the method comprising:
a step of preparing base powder including Ga: 0.1 to 40.0 at % as a component composition by mixing Cu—Ga alloy powder having an average particle size of less than 50 μm with pure copper powder, the Cu—Ga alloy powder including, as a chemical composition, Ga: 10.0 to 75.0 at % and a balance which includes Cu and inevitable impurities;
a step of deoxidizing the base powder at 200° C. or higher in a reducing atmosphere; and
a step of sintering the deoxidized base powder.
